(19) United States
(12) Patent Application Publication
(10) Pub. No.: US 2026/0150656 A1
(43) Pub. Date: May 28, 2026

(54) INTEGRATED CIRCUIT

(71) Applicant: SAMSUNG ELECTRONICS CO., LTD., Suwon-si (KR)

(72) Inventors: Eojin LEE, Suwon-si (KR); Taehyung KIM, Suwon-si (KR)

(73) Assignee: SAMSUNG ELECTRONICS CO., LTD., Suwon-si (KR)

(21) Appl. No.: 19/272,616

(22) Filed: Jul. 17, 2025

(30) Foreign Application Priority Data
Nov. 27, 2024 (KR) 10-2024-0172766

(51) Int. Cl. H01L 23/528; G11C 5/06; G11C 11/419; H01L 23/522; H10B 10/00

(52) U.S. Cl. CPC H10W 20/435; G11C 5/063; G11C 11/419; H10B 10/12; H10B 10/18; H10W 20/42; H10W 20/43

(57) ABSTRACT

An integrated circuit includes a cell region in which cells are disposed, and a peripheral region in which a circuit controlling the cells is disposed. The cell region includes a bit cell region in which bit cells among the cells are disposed, and a dummy region in which dummy cells among the cells are disposed. In the cell region, a bit line pattern and an auxiliary bit line pattern are disposed, the bit line pattern extending in a first direction from a front side of a substrate on which the plurality of cells are disposed, and the auxiliary bit line pattern extending in the first direction from a backside of the substrate. The bit line pattern and the auxiliary bit line pattern are electrically connected to each other in a write mode of the cells.

### CROSS-REFERENCE TO RELATED APPLICATION

This application is based on and claims priority under 35 U.S.C. § 119 to Korean Patent Application No. 10-2024-0172766, filed on Nov. 27, 2024, in the Korean Intellectual Property Office, the disclosure of which being incorporated by reference herein in its entirety.

### BACKGROUND

The present disclosure relates to an integrated circuit, and more particularly, to an integrated circuit including a backside wiring.

Due to the active demand of semiconductor users and the constant efforts of semiconductor manufacturers, technology for semiconductor devices continues to grow remarkably and continues to develop worldwide. In addition, semiconductor manufacturers are not satisfied with this and are trying to make semiconductor devices more miniaturized, more highly integrated, and higher in capacity, while accelerating research and development to speed up by performing more stable and smooth operations. These semiconductor manufacturers'efforts have led to advances in micro-process technology, ultra-small device technology, and circuit design technology, showing remarkable achievements in technologies of semiconductor memory cells such as dynamic random-access memory (DRAM) and static random-access memory (SRAM).

A minimum operating voltage VMIN may be required when designing a circuit of a memory cell, and various technologies are provided to reduce the minimum operating voltage of a random-access memory for low power design.

### SUMMARY

It is an aspect to provide an integrated circuit including a backside wiring capable of securing wiring resources of a top metal of a substrate.

According to an aspect of one or more embodiments, there is provided an integrated circuit comprising a cell region in which a plurality of cells are disposed, and a peripheral region in which a circuit controlling the plurality of cells is disposed. The cell region comprises a bit cell region in which bit cells among the plurality of cells are disposed, and a dummy region in which dummy cells among the plurality of cells are disposed. In the cell region, a bit line pattern and an auxiliary bit line pattern are disposed, the bit line pattern extending in a first direction from a front side of a substrate on which the plurality of cells are disposed, and the auxiliary bit line pattern extending in the first direction from a backside of the substrate, and the bit line pattern and the auxiliary bit line pattern are configured to be electrically connected to each other in a write mode of the plurality of cells.

According to another aspect of one or more embodiments, there is provided an integrated circuit comprising a first region in which a plurality of bit cells are disposed, a second region provided to surround the first region, and a third region in which a circuit controlling the plurality of bit cells is disposed. In the integrated circuit, a bit line pattern and an auxiliary bit line pattern are disposed, the bit line pattern extending in a first direction from a front side of a substrate on which the plurality of bit cells are disposed, and the auxiliary bit line pattern extending in the first direction from a backside of the substrate, and the integrated circuit further comprises a backside connection structure that is connected to the auxiliary bit line pattern and that vertically penetrates the substrate.

According to yet another aspect of one or more embodiments, there is provided an integrated circuit comprising a cell region in which a plurality of cells are arranged, and a peripheral region in which a circuit controlling the plurality of cells is disposed. In the cell region, a bit line, a complementary bit line, an auxiliary bit line and an auxiliary complementary bit line are disposed. The bit line and the complementary bit line are commonly connected to cells arranged in a same column among the plurality of cells. The auxiliary bit line is connected in parallel to the bit line through a switch, and the auxiliary complementary bit line is connected in parallel to the complementary bit line through the switch. The bit line and the complementary bit line are disposed on a front side wiring layer with respect to a substrate on which the plurality of cells are disposed. The auxiliary bit line and the auxiliary complementary bit line are disposed on a backside wiring layer with respect to the substrate. The switch is configured to be turned on in a write mode of the plurality of cells.

### BRIEF DESCRIPTION OF THE DRAWINGS

Various embodiments will be more clearly understood from the following detailed description taken in conjunction with the accompanying drawings, in which:

FIG. 1 is a block diagram illustrating a memory device included in an integrated circuit according to an embodiment;

FIGS. 2A to 2D are diagrams illustrating examples of a device according to some embodiments;

FIG. 3 is a plan view illustrating an integrated circuit according to an embodiment;

FIG. 4 is a circuit diagram illustrating a memory cell according to an embodiment;

FIG. 5A is a block diagram for explaining a connection structure of bit cells and a write driver according to an embodiment, and FIG. 5B is a diagram for easily explaining an arrangement relationship between components according to the connection structure of FIG. 5A;

FIGS. 6A to 6C are layout diagrams for explaining regions in which a bit line and an auxiliary bit line are disposed, according to some embodiments;

FIGS. 7A to 7D are layout diagrams for explaining a region in which a bit line and an auxiliary bit line are disposed, according to some embodiments;

FIG. 8 is a cross-sectional view of an integrated circuit according to an embodiment;

FIG. 9 is a cross-sectional view of an integrated circuit according to an embodiment;

FIG. 10 is a cross-sectional view of an integrated circuit according to an embodiment;

FIG. 11 is a cross-sectional view of an integrated circuit according to an embodiment;

FIG. 12 is a flowchart illustrating a method of manufacturing an integrated circuit, according to an embodiment;

FIG. 13 is a block diagram illustrating a system-on-chip according to an embodiment; and

FIG. 14 is a block diagram illustrating a computing system including a memory storing a program according to an embodiment.

### DETAILED DESCRIPTION

Hereinafter, various embodiments are described in detail with reference to the accompanying drawings. Like reference numerals are used for like components in the drawings, and redundant descriptions thereof are omitted for conciseness.

Herein, the X-axis direction may be referred to as a first direction, the Y-axis direction may be referred to as a second direction, and the Z-axis direction may be referred to as a vertical direction. A plane formed by the X-axis and the Y-axis may be referred to as a horizontal plane, a component positioned in a +Z-axis direction relative to other components may be referred to as being above other components, and a component positioned in a −Z-axis direction relative to other components may be referred to as being below other components.

An integrated circuit may be designed by arranging a plurality of standard cells. A standard cell is a unit of layout of an integrated circuit and may be referred to as a “cell” depending on an embodiment. A standard cell may include a plurality of transistors to perform a function. The function may be predetermined. A standard cell method is a method of preparing standard cells with various functions in advance and designing a dedicated large-scale integrated circuit that meets the specifications of customers or users by combining the standard cells. Standard cells are designed and verified in advance and registered in a standard cell library, and integrated circuits may be designed by performing logic design, placement, and routing by combining standard cells using computer-aided design (CAD).

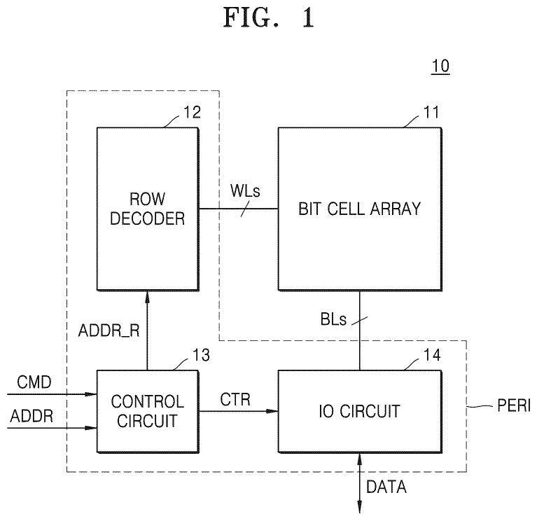

FIG. 1 is a block diagram illustrating a memory device 10 included in an integrated circuit according to an embodiment.

Referring to FIG. 1, the memory device 10 may include a bit cell array 11, a row decoder 12, a control circuit 13, and an input/output (I/O) circuit 14. The row decoder 12, the control circuit 13, and the I/O circuit 14 may be collectively referred to as a periphery circuit PERI. According to an embodiment, the periphery circuit PERI may further include a command buffer, an address buffer, a write driver, and/or a voltage generator.

The memory device 10 may receive a command CMD, an address ADDR, and data DATA. For example, the memory device 10 may receive the command CMD for instructing writing, the address ADDR, and the data DATA and may store the received data DATA in a region of the bit cell array 11 corresponding to the address ADDR. Similarly, the memory device 10 may receive the command CMD for instructing reading and the address ADDR, and may output the data DATA stored in the region of a bit cell array 11 corresponding to the address ADDR to the outside.

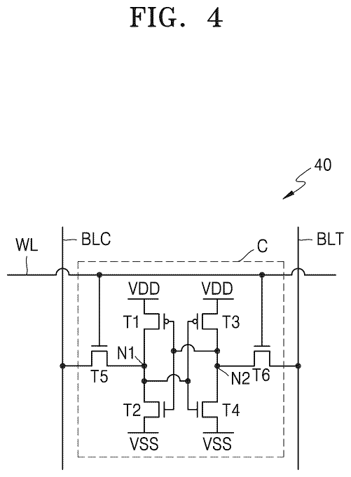

The bit cell array 11 may include a plurality of bit cells or memory cells accessed by a plurality of word lines WL and a plurality of bit lines BL. In some embodiments, the bit cells included in the bit cell array 11 may be volatile memory cells, such as static random access memory (SRAM), dynamic random access memory (DRAM), etc. In some embodiments, the memory cells included in the bit cell array 11 may be non-volatile memory cells, such as flash memory, resistive random access memory (RRAM), etc. The embodiments are described with reference mainly to the SRAM, as described with reference to FIG. 4, but the embodiments are not limited thereto.

The control circuit 13 may generate a row address ADDR_R and a control signal CTR based on the command CMD and the address ADDR. For example, the control circuit 13 may identify a read command by decoding the command CMD and generate the row address ADDR_R and the control signal CTR to read data DATA from the bit cell array 11. Similarly, the control circuit 13 may identify a write command by decoding the command CMD and generate the row address ADDR_R and the control signal CTR to write data DATA to the bit cell array 11

The row decoder 12 may be connected to the bit cell array 11 through the plurality of word lines WL and may activate one of the plurality of word lines WL according to the row address ADDR_R. Accordingly, bit cells connected to the activated word line among the bit cells included in the bit cell array 11 may be selected. For example, the row decoder 12 may include a row driver.

The I/O circuit 14 may be connected to the bit cell array 11 through the plurality of bit lines BL and may perform a read operation or a write operation according to the control signal CTR. For example, the I/O circuit 14 may include a column driver. The column driver may detect current and/or voltage of the plurality of bit lines BL or apply current and/or voltage to the plurality of bit lines BL at a timing determined based on the control signal CTR.

In an embodiment, the I/O circuit 14 may include a plurality of logic cells or a plurality of standard cells. According to an embodiment, the plurality of standard cells may be referred to as a plurality of I/O slices. For example, the plurality of standard cells may be respectively connected to the plurality of bit cells via the plurality of bit lines BL. For example, the plurality of standard cells may include write/read circuits. For example, the plurality of standard cells may include sense amplifiers. For example, the plurality of standard cells may include column drivers or write drivers

As will be described below with reference to the drawings, the memory device 10 may include patterns extending from a backside wiring layer of a substrate and a backside connection structure penetrating the substrate in a vertical direction. The backside connection structure may include a backside contact structure and a backside via structure. The patterns extending from the backside wiring layer may be used for auxiliary routing of bit signals (e.g., a bit line BLC and a complementary bit line BLT). Accordingly, routing resources of a top metal in the bit cell array 11 may increase, and thus, the performance and reliability of the memory device 10 may increase. In some embodiments, the backside connection structure may be disposed in a second region R2 or a third region R_PERI to be described below, in terms of reducing the overhead of the area.

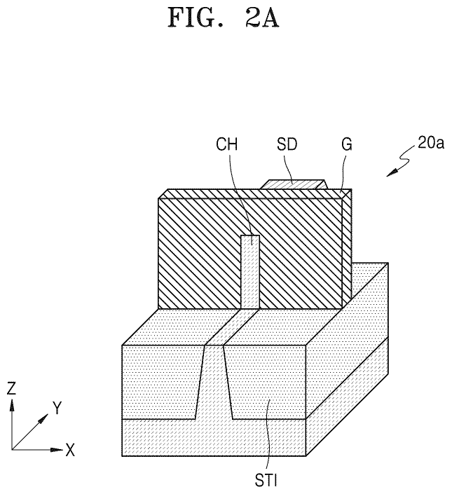

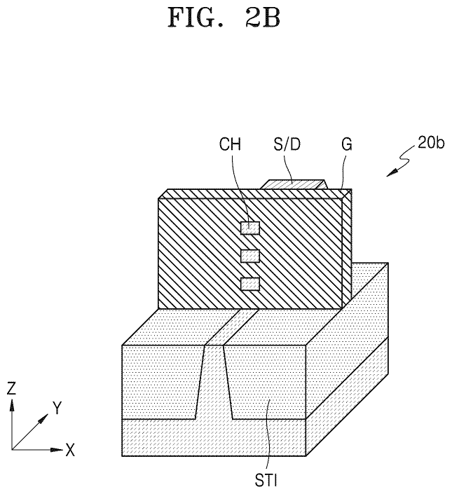

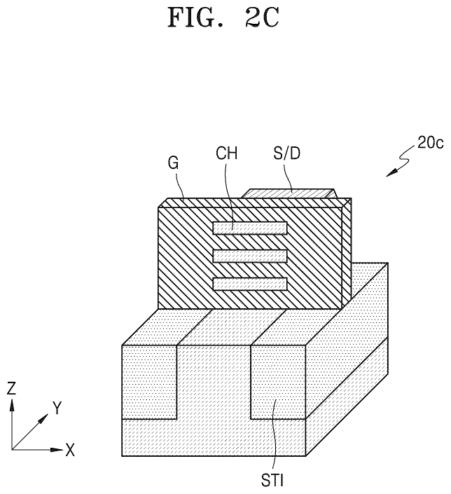

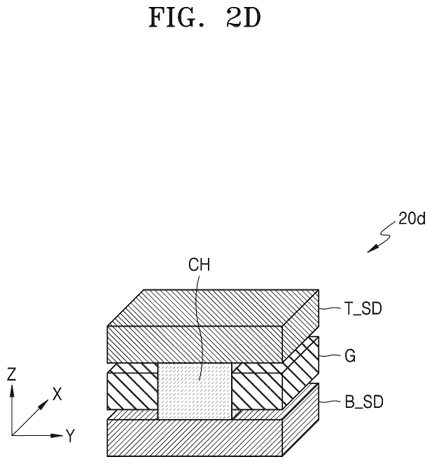

FIGS. 2A to 2D are diagrams illustrating examples of a device according to some embodiments. For example, FIG. 2A shows a FinFET 20a, FIG. 2B shows a gate-all-around field effect transistor (GAAFET) 20b, FIG. 2C shows a multi-bridge channel field effect transistor (MBCFET) 20c, and FIG. 2D shows a vertical field effect transistor (VFET) 20d. For convenience of illustration, FIGS. 2A to 2C illustrate a state in which one of two source/drain regions is removed, and FIG. 2D illustrates a cross-section of the VFET 20d cut into a plane parallel to a plane formed by the Y-axis and the Z-axis and passing through a channel CH of the VFET 20d.

Referring to FIG. 2A, the FinFET 20a may be formed by a fin-shaped active pattern extending in a Y-axis direction and a gate electrode G extending in an X-axis direction between shallow trench isolations (STIs). Source/drain regions SD may be formed on both sides of the gate electrode G, and thus a source and a drain may be spaced apart from each other in the Y-axis direction. An insulating layer may be formed between the channel CH and the gate electrode G. In some embodiments, the FinFET 20a may be formed by a plurality of active patterns spaced apart from each other in the X-axis direction and the gate electrode G, and may have an extended channel.

Referring to FIG. 2B, the GAAFET 20b may be formed by active patterns spaced apart from each other in a Z-axis direction and extending in the Y-axis direction, that is, nanowires, and the gate electrode G extending in the X-axis direction. The source/drain regions SD may be formed on both sides of the gate electrode G, and thus the source and the drain may be spaced apart from each other in the Y-axis direction. An insulating layer may be formed between the channel CH and the gate electrode G. It is noted that the number of nanowires included in the GAAFET is not limited to that shown in FIG. 2B.

Referring to FIG. 2c, the MBCFET 20c may be formed by active patterns spaced apart from each other in the Z-axis direction and extending in the Y-axis direction, that is, nanosheets, and the gate electrode G extending in the X-axis direction. The source/drain regions SD may be formed on both sides of the gate electrode G, and thus the source and the drain may be spaced apart from each other in the Y-axis direction. An insulating layer may be formed between the channel CH and the gate electrode G. It is noted that the number of nanosheets included in the MBCFET is not limited to that shown in FIG. 2C.

Referring to FIG. 2D, the VFET 20d may include a top source/drain region T_SD and a bottom source/drain region B_SD spaced apart from each other in the Z-axis direction with the channel CH disposed therebetween. The VFET 20d may include the gate electrode G surrounding the periphery of the channel CH between the top source/drain region T_SD and the bottom source/drain region B_SD. An insulating layer may be formed between the channel CH and the gate electrode G.

Hereinafter, an integrated circuit including the FinFET 20a or the MBCFET 20c will be mainly described, but it is noted that devices included in the integrated circuit are not limited to the examples of FIGS. 2A to 2D. For example, in some embodiments, the integrated circuit may include a ForkFET in which an N-type transistor and a P-type transistor have a closer structure by separating nanosheets for the P-type transistor and nanosheets for the N-type transistor by a dielectric wall. In some embodiments, the integrated circuit may include a bipolar junction transistor as well as a FET such as a complementary field effect transistor (CFET), a negative capacitance field effect transistors (NCFET), a carbon nanotube (CNT) FET, etc.

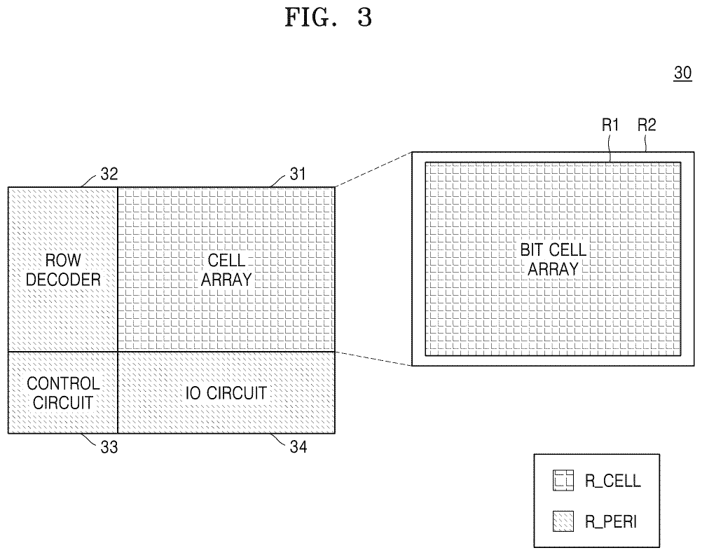

FIG. 3 is a plan view illustrating an integrated circuit 30 according to an embodiment.

Referring to FIG. 3, the integrated circuit 30 may include at least one cell array disposed in a cell region R_CELL and a peripheral circuit disposed in a peripheral region R_PERI. For example, the integrated circuit 30 may represent an example of a layout of an integrated circuit corresponding to the memory device 10 of FIG. 1. For example, a cell array 31 may be disposed in the cell region R_CELL, and a row decoder 32, a control circuit 33, and an input/output circuit 34 may be disposed in the peripheral region R_PERI. According to an embodiment, the row decoder 32 may be referred to as a row driver, and the input/output circuit 34 may be referred to as a column driver.

The cell array may include a cell array region R1 and a dummy region R2. A bit cell array including a plurality of bit cells may be disposed in the cell array region R1. The dummy region R2 surrounds the cell array region R1, and may also be referred to as an outer region, a transition region, or a termination region. According to an example, a plurality of dummy cells may be disposed in the dummy region R2. According to another example, the dummy region R2 may be a region in which no bit cells are disposed. In the disclosure, for convenience of description, the cell array region R1 is referred to as a first region, the dummy region R2 is referred to as a second region, and the peripheral region R_PERI is referred to as a third region, and the above terms and reference numerals thereof may be described interchangeably.

Referring to the drawings described below, auxiliary patterns extending from a backside wiring layer below a substrate may be disposed to extend over the first region and the second regions, or the first region to the third region, and a backside connection structure may be provided to assist physical connection between the auxiliary pattern extending from the backside wiring layer and a pattern extending from a front side wiring layer. When the auxiliary pattern is disposed to extend over the first region and the second region on the backside wiring layer, the backside connection structure for connecting the auxiliary pattern and the pattern extending from the front side wiring layer may be disposed in the second region. When the auxiliary pattern is disposed to extend over the first region, the second region, and the third region on the backside wiring layer, the backside connection structure for connecting the auxiliary pattern and the pattern extending from the front side wiring layer may be disposed in the third region. According to an example, when the backside contact structure is disposed in the second region to connect the auxiliary pattern and the pattern extending from the front side wiring layer, the routing of wiring may be secured without causing the overhead of the area by utilizing an unused dummy cell region. According to another example, when a backside via structure for connecting the auxiliary pattern and the pattern extending from the front side wiring layer is disposed in the third region, the routing of wiring may be secured while reducing the overhead of the area to the maximum by utilizing the peripheral region R_PERI at a position adjacent to the cell region R_CELL.

FIG. 4 is a circuit diagram illustrating a memory cell according to an embodiment.

For example, the circuit diagram of FIG. 4 illustrates an equivalent circuit 40 corresponding to one memory cell included in the bit cell array 11 of FIG. 1. In some embodiments, the bit cell array 11 may include a plurality of memory cells each having the same structure as the memory cell C.

Referring to FIG. 4, the memory cell C may be connected to the word line WL, and memory cells disposed in the same row as the memory cell C may be commonly connected to the word line WL. The memory cell C may be connected to the bit line BLC and the complementary bit line BLT, and memory cells disposed in the same column as the memory cell C may be commonly connected to the bit line BLC and the complementary bit line BLT. A plurality of bit lines BLC and a plurality of complementary bit lines BLT may be alternately disposed.

The memory cell C may include a first transistor T1, a second transistor T2, a third transistor T3, a fourth transistor T4, a fifth transistor T5, and a sixth transistor T6, and may be referred to as a 6T SRAM cell. As shown in FIG. 4, the first transistor T1 and the third transistor T3 may be PFETs, and the second transistor T2 and the fourth to sixth transistors T4 to T6 may be NFETs. The memory cell C may include a cross-coupled inverter pair between a node to which a positive supply voltage VDD is applied and a node to which a negative supply voltage (or ground potential) VSS is applied. For example, a first inverter and a second inverter may be cross-coupled in a first node N1 and a second node N2, the first inverter may include the first transistor T1 and the second transistor T2, and the second inverter may include the third transistor T3 and the fourth transistor T4.

The fifth transistor T5 and the sixth transistor T6 may electrically connect the first inverter and the second inverter to the bit line BLC and the complementary bit line BLT, respectively, by an activated word line WL (e.g., having a high level voltage). For example, the fifth transistor T5 may be connected to the first node N1 to which an output of the first inverter and an input of the second inverter are connected, and electrically connect the first node N1 to the bit line BLC in response to the activated word line WL. The sixth transistor T6 may be connected to the second node N2 to which an input of the first inverter and an output of the second inverter are connected, and electrically connect the second node N2 to the complementary bit line BLT in response to the activated word line WL. Herein, the fifth transistor T5 and the sixth transistor T6 may be referred to as pass transistors. According to an example, transistors included in the memory cell C may be implemented in a structure of various devices disclosed in FIGS. 2A to 2D.

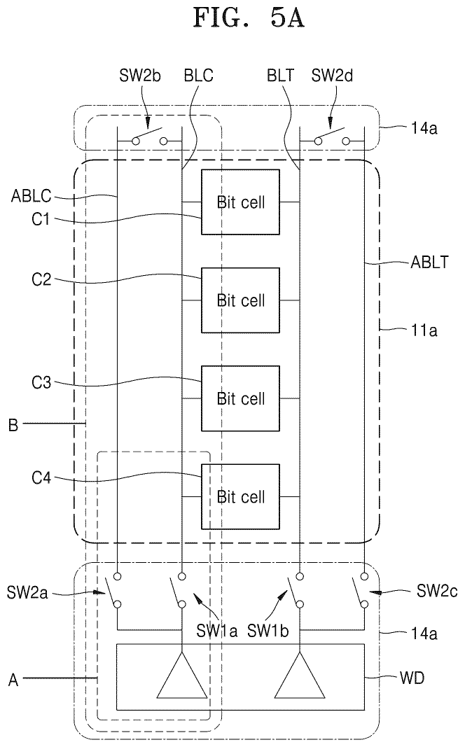

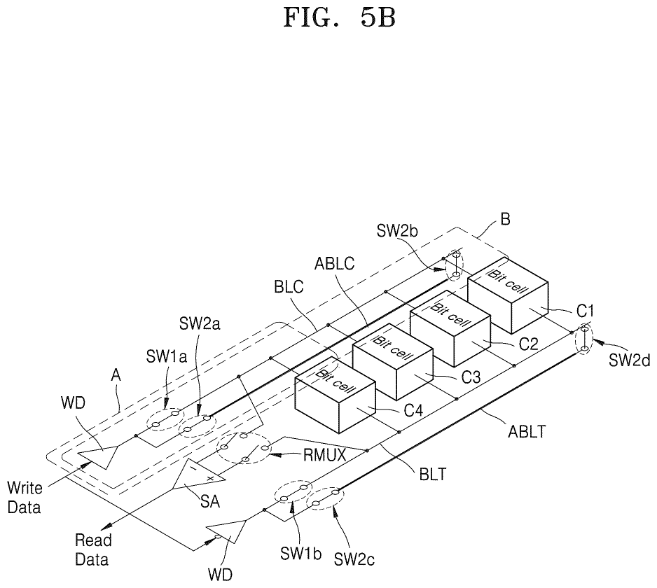

The size of the transistor may be reduced due to the development of a semiconductor process, and the size of the memory cell may be reduced. In addition, routing resources for patterns to provide the positive supply voltage VDD or the negative supply voltage VSS to the memory cells, as well as patterns corresponding to the word lines WL, the bit lines BLC, and the complementary bit lines BLT connected to the memory cells may be limited. Accordingly, parasitic components of the pattern, such as parasitic resistance and/or parasitic capacitance, may increase, and the performance and reliability of a memory device may be limited. In addition, a resistance value by the bit line BLC and the complementary bit line BLT may also affect a write margin when performing a write operation on the memory cell. According to an example, in order to improve the write margin, an auxiliary bit line ABLC (FIG. 5A) and an auxiliary complementary bit line ABLT (FIG. 5A) respectively connected in parallel to the bit line BLC and the complementary bit line BLT may be additionally connected to the memory cell. Accordingly, during the write operation of the memory cell, write performance may be improved by reducing the voltage of a node included in the memory cell C. This will be described in more detail with reference to FIGS. 5A and 5B.

FIG. 5A is a block diagram for explaining a connection structure of bit cells and a write driver according to an embodiment. FIG. 5B is a diagram for easily explaining an arrangement relationship between components according to the connection structure of FIG. 5A.

FIG. 5A shows a plurality of memory cells C1, C2, C3, and C4 included in a bit cell array 11a and commonly connected to the bit line BLT and the complementary bit line BLT. Each of the plurality of memory cells C1, C2, C3, and C4 may be a bit cell and may correspond to the structure of the memory cell C shown in FIG. 4. The plurality of memory cells C1, C2, C3, and C4 may be provided in the same column to share the bit line BLC and the complementary bit line BLT.

According to an embodiment, the bit cell array 11a may further include the auxiliary bit line ABLC connected in parallel to the bit line BLC and the auxiliary complementary bit line ABLT connected in parallel to the complementary bit line BLT. The auxiliary bit line ABLC and the auxiliary complementary bit line ABLT may extend in the same direction as the bit line BLC and the complementary bit line BLT. The bit line BLC, the complementary bit line BLT, the auxiliary bit line ABLC, and the auxiliary complementary bit line ABLT may be connected to a write driver WD. Data may be written to a selected cell through the bit line BLC and the complementary bit line BLT according to a signal and data applied from the write driver WD.

An input/output circuit 14a may include the write driver WD, first switches SW1a and SW1b, and second switches SW2a, SW2b, SW2c, and SW2d. The first switch SW1a may connect the write driver WD to the bit line BLC, and the first switch SW1b may connect the write driver WD to the complementary bit line BLT. According to whether the first switches SW1a and SW1b are turned on, whether the write driver WD, the bit line BLC, and the complementary bit line BLT are connected to each other may be determined. When the first switch SW1a is turned on, the write driver WD and the bit line BLC may be connected to each other, and when the first switch SW1b is turned on, the write driver WD and the complementary bit line BLT may be connected to each other.

The second switches SW2a and SW2b may connect the bit line BLC to the auxiliary bit line ABLC in parallel. The second switches SW2c and SW2d may connect the complementary bit line BLT to the auxiliary complementary bit line ABLT in parallel. According to whether the second switches SW2a, SW2b, SW2c, and SW2d are turned on, whether the bit line BLC is electrically connected to the auxiliary bit line ABLC, and the complementary bit line BLT is electrically connected to the auxiliary complementary bit line ABLT may be determined. When the second switches SW2a and SW2b are turned on, the bit line BLC and the auxiliary bit line ABLC may be electrically connected to each other. When the second switches SW2c and SW2d are turned on, the complementary bit line BLT and the auxiliary complementary bit line ABLT may be electrically connected to each other.

According to an embodiment, in a write mode in which data is written to a memory cell through the write driver WD, the first switches SW1a and SW1b and the second switches SW2a, SW2b, SW2c, and SW2d may be turned on. Accordingly, in the write mode in which data is written to a cell, the bit line BLC may be connected in parallel to the auxiliary bit line ABLC, and the complementary bit line BLT may be connected in parallel to the auxiliary complementary bit line ABLT. Accordingly, a write path from the write driver WD is added in the write mode, and thus the effective resistance of the bit line BLC and the complementary bit line BLT may be reduced through the auxiliary bit line ABLC and the auxiliary complementary bit line BLT having a smaller resistance, thereby improving the write margin of the write driver WD by reducing the voltage of a data node of a bit cell.

In the disclosure, in addition to this structure, wiring resources of a top metal may be secured by differentiating positions at which the bit line BLC and the complementary bit line BLT are disposed and positions at which the auxiliary bit line ABLC and the auxiliary complementary bit line ABLT are disposed.

FIG. 5B is a diagram for explaining an arrangement relationship between components according to a connection structure between bit lines of FIG. 5A.

FIG. 5B shows three-dimensionally the bit line BLC, the complementary bit line BLT, the auxiliary bit line ABLC, and the auxiliary complementary bit line ABLT respectively connected to the plurality of memory cells C1, C2, C3, and C4 shown in FIG. 5A. The bit line BLC may be connected to the write driver WD through the first switch SW1a, and the bit line BLC and the auxiliary bit line ABLC may be connected in parallel to each other through the second switches SW2a and SW2b. The complementary bit line BLT may be connected to the write driver WD through the first switch SW1b, and the complementary bit line BLT and the auxiliary complementary bit line ABLT may be connected in parallel to each other through the second switches SW2c and SW2d. According to an example, an amplifier SA may be connected to the bit line BLC and the complementary bit line BLT through a third switch RMUX. According to an example, when the third switch RMUX is turned on, the bit line BLC and the complementary bit line BLT may be connected to the amplifier SA to read data stored in the memory cells C1, C2, C3, and C4. According to an example, in a read mode, the third switch RMUX may be turned on, and the first switches SW1a and SW1b and the second switches SW2a, SW2b, SW2c, and SW2d may be turned off.

Referring to FIG. 5B, the bit line BLC and the complementary bit line BLT may be disposed at positions different from the auxiliary bit line ABLC and the auxiliary complementary bit line ABLT. According to an example, the bit line BLC and the complementary bit line BLT may be disposed on a front side wiring layer with respect to a substrate on which the memory cells C1, C2, C3, and C4 are disposed, and the auxiliary bit line ABLC and the auxiliary complementary bit line ABLT may be disposed on a backside wiring layer with respect to the substrate. According to an example, the auxiliary bit line ABLC and the auxiliary complementary bit line ABLT may be electrically connected to the bit line BLC and the complementary bit line BLT, respectively, in a write operation of a cell. In the disclosure, the meaning of electrically connecting A to B may mean a state in which a current may flow between A and B, and data or signals may be transmitted between A and B. In the disclosure, the auxiliary bit line ABLC and the auxiliary complementary bit line ABLT used in the write operation mode of the cell are disposed on the backside wiring layer of the substrate, thereby securing a degree of freedom of wiring and simultaneously securing wiring resources of a top metal, and the write margin and write time may be maximized by using the backside wiring metal with excellent resistance characteristics.

According to an embodiment, the bit cell array 11a may include patterns corresponding to the auxiliary bit line ABLC and the auxiliary complementary bit line ABLT on the backside wiring layer below the substrate, and further include a structure for connecting auxiliary patterns on the backside wiring layer to the front side wiring layer above the substrate, which provides various connection structures capable of improving the write margin by reducing the resistance of bit lines and having no overhead of the area.

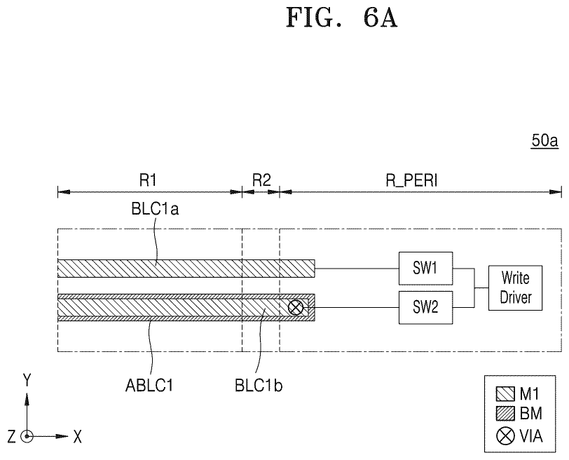

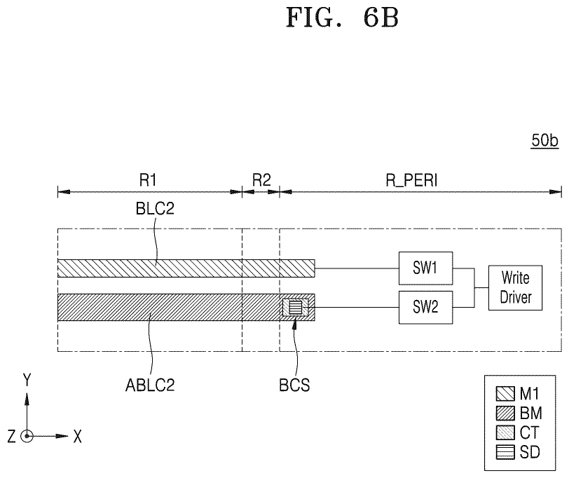

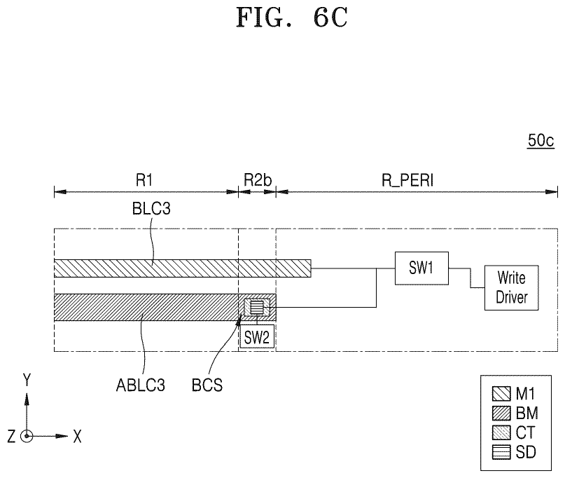

FIGS. 6A to 6C are layout diagrams for explaining regions in which a bit line and an auxiliary bit line are disposed according to some embodiments.

In FIGS. 6A to 6C, for convenience of description and conciseness, the remaining lines (e.g., a word line, a gate line, etc.) excluding the bit line and the auxiliary bit line are omitted. According to an example, FIGS. 6A to 6C may be layout drawings for explaining embodiments in which components corresponding to region A of FIGS. 5A and 5B are respectively disposed in regions of an integrated circuit. In FIGS. 6A to 6C, only the relationship between the bit line BLC and the auxiliary bit line ABLC is described, but it should be noted that the following descriptions may be applied equally to the complementary bit line BLT and the auxiliary complementary bit line ABLT.

Referring to FIG. 6A, an integrated circuit 50a may include a first front side wiring layer M1 and a backside wiring layer BM. The first front side wiring layer M1 may be a first wiring layer disposed on a front side with respect to a substrate. The backside wiring layer BM may be a wiring layer disposed on a backside with respect to the substrate. Patterns BLC1a and BLC1b corresponding to bit lines may be disposed to extend in a first direction on the first front side wiring layer M1, and a pattern ABLC1 corresponding to the auxiliary bit line may be disposed to extend in the first direction on the backside wiring layer BM. The patterns BLC1a and BLC1b corresponding to the bit lines and the pattern ABLC1 corresponding to the auxiliary bit line may be formed to extend over the first region R1, the second region R2, and the third region R_PERI. According to an example, the length of the pattern ABLC1 corresponding to the auxiliary bit line in the Y-axis direction may be greater than the length of the patterns BLC1a and BLC1b corresponding to the bit lines in the Y-axis direction, but embodiments are not limited thereto. In the disclosure, a pattern corresponding to the bit line may be described as a bit line pattern, and a pattern corresponding to the auxiliary bit line may be described as an auxiliary bit line pattern.

According to an example, the write driver WD, the first switch SW1, and the second switch SW2 included in the input/output circuit 14a (FIG. 5A) may be disposed in the third region R_PERI. The write driver WD, the first switch SW1, and the second switch SW2 correspond to the components of the write driver WD, the first switch SW1a, and the second switch SW2a described with reference to FIGS. 5A and 5B, and thus redundant descriptions thereof are omitted for conciseness.

According to an example, the pattern BLC1a corresponding to the bit line shown in FIG. 6A may correspond to the bit line BLC of FIG. 5A, and the pattern ABLC1 corresponding to the auxiliary bit line shown in FIG. 6A may correspond to the auxiliary bit line ABLC of FIG. 5A. The pattern BLC1b corresponding to the bit line shown in FIG. 6A may correspond to a bit line connected to another memory cell not shown in FIG. 5A. The bit line BLC and the auxiliary bit line ABLC of FIG. 5A are to be connected in parallel with each other, and electrical connection therebetween may be determined by the second switches SW2a and SW2b, and thus the bit line BLC and the auxiliary bit line ABLC need not to be physically connected on the integrated circuit 50a. The pattern BLC1a corresponding to the bit line and the pattern ABLC1 corresponding to the auxiliary bit line are not directly connected to each other, and the integrated circuit 50a has a structure for connecting one end of the second switch SW2 to the pattern ABLC1 corresponding to the auxiliary bit line, and the integrated circuit 50a may include a backside via structure VIA extending in the Z-axis direction. According to an example, the backside via structure VIA may physically connect the pattern ABLC1 corresponding to the auxiliary bit line to the pattern BLC1b corresponding to the bit line in a third direction.

According to an example, the pattern BLC1a corresponding to the bit line disposed on the front side of the substrate may be connected to one end of the first switch SW1, and the pattern BLC1b corresponding to the bit line disposed on the front side of the substrate may be connected to one end of the second switch SW2. Electrical connection with the pattern ABLC1 corresponding to the auxiliary bit line may be possible through the backside via structure VIA connected to the pattern BLC1b corresponding to the bit line connected to one end of the second switch SW2 in a vertical direction.

According to an embodiment of FIG. 6A, the pattern BLC1b corresponding to the bit line and the pattern ABLC1 corresponding to the auxiliary bit line may be physically connected to each other through the backside via structure VIA extending in the Z-axis direction, and when the second switch SW2 is turned on, the pattern BLC1a corresponding to the bit line and the pattern ABLC1 corresponding to the auxiliary bit line may be electrically connected to each other through the backside via structure VIA. According to an example of FIG. 6A, the backside via structure VIA may be disposed in the third region R_PERI, and to this end, the patterns BLC1a and BLC1b corresponding to the bit lines and the pattern ABLC1 corresponding to the auxiliary bit line may be disposed to extend into the third region R_PERI.

Referring to FIG. 6B, an integrated circuit 50b may include the first front side wiring layer M1 and the backside wiring layer BM. In the description of FIG. 6B, a description of the configuration redundant with that described with reference to FIG. 6A will be omitted for conciseness.

Referring to FIG. 6B, a pattern BLC2 corresponding to the bit line may be disposed to extend in a first direction on the first front side wiring layer M1, and a pattern ABLC2 corresponding to the auxiliary bit line may be disposed to extend in the first direction on the backside wiring layer BM.

The difference between the integrated circuit 50a of FIG. 6A and the integrated circuit 50b of FIG. 6B is that the integrated circuit 50b of FIG. 6B has a structure for connecting one end of the second switch SW2 to the pattern ABLC2 corresponding to the auxiliary bit line, and may include a backside contact structure BCS. According to an example, the backside contact structure BCS may be in contact with and connected to the pattern ABLC2 corresponding to the auxiliary bit line and may extend in the Z-axis direction. The backside contact structure BCS may be physically connected to a transistor formed on a substrate, and one end of the second switch SW2 may be connected to one end of the transistor connected to the backside contact structure BCS. According to an example, the backside contact structure BCS may include a backside contact CT extending in the vertical direction. The backside contact CT may be in contact with an active region included in the transistor formed on the substrate. A source/drain region S/D may be formed in an upper portion of the active region. According to an example, the backside contact CT, the active region, and the source/drain region S/D may be formed by being stacked in the vertical direction. According to another embodiment, a via (not shown) may be connected between the backside contact CT and the pattern ABLC2 corresponding to the auxiliary bit line.

The pattern ABLC1 corresponding to the auxiliary bit line of the integrated circuit 50a of FIG. 6A may be different from the pattern ABLC2 corresponding to the auxiliary bit line of the integrated circuit 50b of FIG. 6B in that the pattern ABLC1 is connected to one end of the second switch SW2 through the backside via structure VIA and the pattern BLC1b corresponding to another bit line formed on the first front side wiring layer M1, whereas the pattern ABLC2 is connected to one end of the second switch SW2 through the backside contact structure BCS and the transistor formed on the substrate. According to an example, the backside contact structure BCS may be disposed in the third region R_PERI, and to this end, the pattern BLC2 corresponding to the bit line and the pattern ABLC2 corresponding to the auxiliary bit line may be disposed to extend to the third region R_PERI.

Referring to FIG. 6C, an integrated circuit 50c may include the first front side wiring layer M1 and the backside wiring layer BM. In the description of FIG. 6C, a description of the configuration redundant with that described with reference to FIGS. 6A and 6B will be omitted for conciseness.

Referring to FIG. 6C, a pattern BLC3 corresponding to the bit line may be disposed to extend in the first direction on the first front side wiring layer M1, and a pattern ABLC3 corresponding to the auxiliary bit line may be disposed to extend in the first direction on the backside wiring layer BM. The integrated circuit 50c of FIG. 6C is a structure for connecting one end of the second switch SW2 to the pattern ABLC3 corresponding to the auxiliary bit line, and may include the backside contact structure BCS.

The backside contact structure BCS and the second switch SW2 included in the integrated circuit 50c of FIG. 6C may be disposed in the second region R2. Accordingly, the pattern ABLC3 corresponding to the auxiliary bit line may be disposed to extend only to the second region R2, and may not be formed in the third region R_PERI. The integrated circuit 50c of FIG. 6C may be different from the integrated circuit 50b of FIG. 6B in a region in which the backside contact structure BCS and the second switch SW2 are disposed. According to an embodiment, the backside contact structure BCS and the second switch SW2 are disposed in the second region R2, which is a region in which a dummy cell is disposed, and thus a layout structure of a backside wiring may be possible without the overhead of an area.

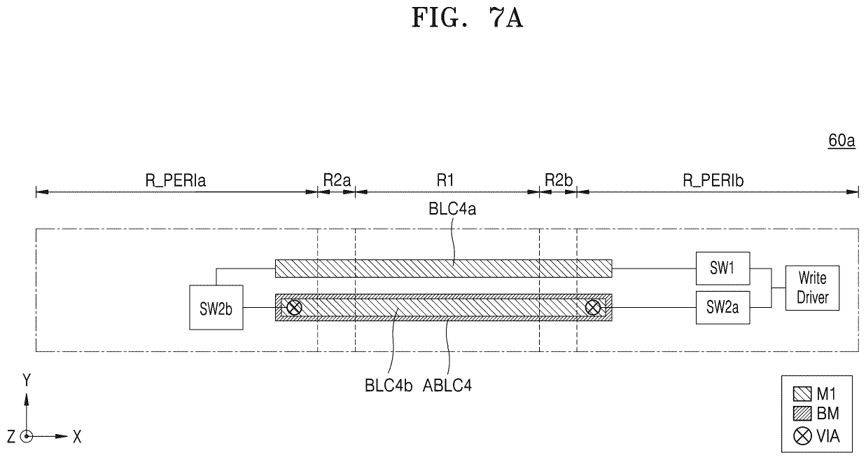

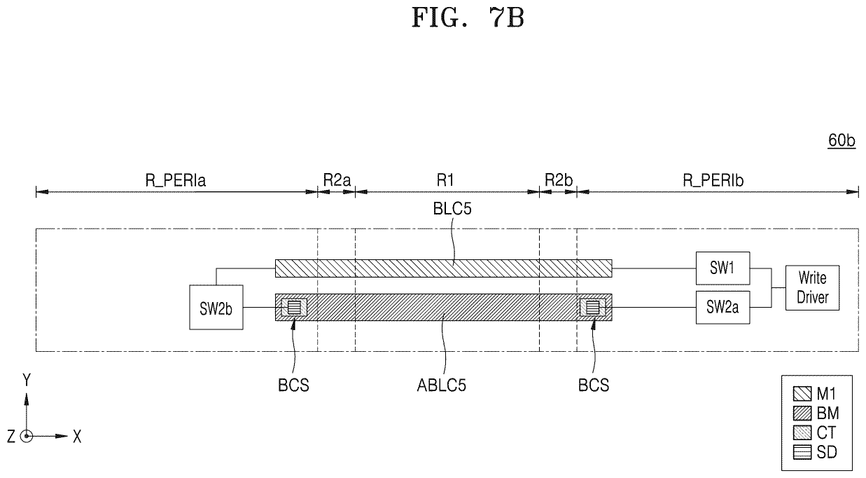

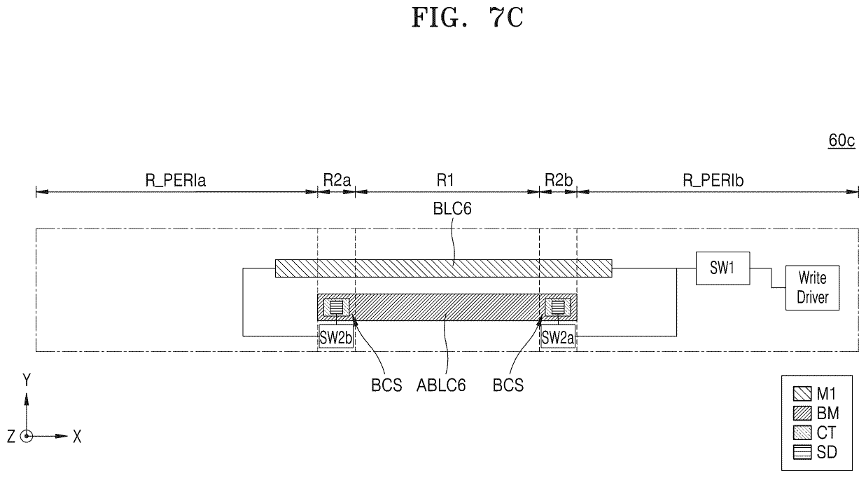

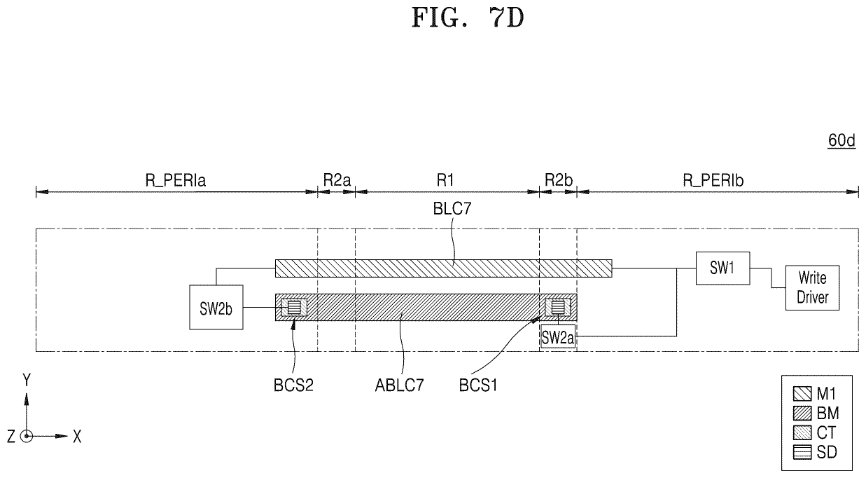

FIGS. 7A to 7D are layout diagrams for explaining regions in which a bit line and an auxiliary bit line are disposed according to some embodiments.

In FIGS. 7A to 7D, for convenience of description and conciseness, the remaining lines (e.g., a word line, a gate line, etc.) excluding the bit line and the auxiliary bit line are omitted. According to an example, FIGS. 7A to 7D may be layout drawings for explaining embodiments in which components corresponding to region B of FIGS. 5A and 5B are respectively disposed in regions of an integrated circuit. In the following drawings, the relationship between the bit line BLC and the auxiliary bit line ABLC is described, but it should be noted that the following descriptions may be applied equally to the complementary bit line BLT and the auxiliary complementary bit line ABLT.

FIGS. 7A to 7D show a layout of the integrated circuit including the first region R1, second regions R2a and R2b disposed to surround both ends of the first region R1, and third regions R_PERIa and R_PERIb disposed to surround both ends of the second regions R2a and R2b. The layout of FIGS. 7A to 7D may include a part of the layout of the integrated circuit of FIGS. 6A to 6C.

Referring to FIG. 7A, an integrated circuit 60a may include the first front side wiring layer M1 and the backside wiring layer BM. The first front side wiring layer M1 may be a first wiring layer disposed on a front side with respect to a substrate. The backside wiring layer BM may be a wiring layer disposed on a backside with respect to the substrate. Patterns BLC4a and BLC4b corresponding to bit lines may be disposed to extend in the first direction on the first front side wiring layer M1, and a pattern ABLC4 corresponding to the auxiliary bit line may be disposed to extend in the first direction on the backside wiring layer BM. The patterns BLC4a and BLC4b corresponding to the bit lines and the pattern ABLC4 corresponding to the auxiliary bit line may be formed to extend over the first region R1, the second regions R2a and R2b, and the third regions R_PERIa and R_PERIb.

According to an example, the write driver WD, the first switch SW1, and the second switches SW2a and SW2b included in the input/output circuit 14a (FIG. 5A) may be disposed in the third regions R_PERIa and R_PERIb. The write driver WD, the first switch SW1, and the second switches SW2a and SW2b correspond to components of the write driver WD, the first switch SW1a, and the second switches SW2a and SW2b described with reference to FIGS. 5A and 5B, and thus redundant descriptions thereof are omitted for conciseness.

The structure of the first region R1, the second region R2b, and the third region R_PERIb of the integrated circuit 60a of FIG. 7a may correspond to the structure of the integrated circuit 50a shown in FIG. 6a, and thus, redundant descriptions thereof are omitted for conciseness, and the second region R2a and the third region R_PERIa of the integrated circuit 60a are described.

According to an example, the pattern BLC4a corresponding to the bit line and the pattern ABLC4 corresponding to the auxiliary bit line are not directly connected to each other, and the integrated circuit 60a has a structure for connecting one end of the second switch SW2b to the pattern ABLC4 corresponding to the auxiliary bit line, and the integrated circuit 60a may include the two backside via structures VIA extending in the Z-axis direction. According to an example, the backside via structure VIA may physically connect the pattern ABLC4 corresponding to the auxiliary bit line to the pattern BLC4b corresponding to the bit line in the third direction. Referring to FIG. 7A, the backside via structure VIA may be disposed in each of the third regions R_PERIa and R_PERIb. The structure of the backside via structure VIA is redundant with that described with reference to FIG. 6A, and thus a description thereof will be omitted.

According to an embodiment of FIG. 7A, the pattern BLC4b corresponding to the bit line and the pattern ABLC4 corresponding to the auxiliary bit line may be physically connected to each other through the two backside via structures VIA extending in the Z-axis direction, and when the second switches SW2a and SW2b are turned on, the pattern BLC4a corresponding to the bit line and the pattern ABLC4 corresponding to the auxiliary bit line may be electrically connected to each other through the backside via structure VIA. According to an example of FIG. 7A, the backside via structure VIA may be disposed in the third regions R_PERIa and R_PERIb, and to this end, the patterns BLC4a and BLC4b corresponding to the bit line and the patterns ABLC4 corresponding to the auxiliary bit line may be disposed to extend to the third regions R_PERIa and R_PERIb.

Referring to FIG. 7B, an integrated circuit 60b may include the first front side wiring layer M1 and the backside wiring layer BM. Referring to FIG. 7B, a pattern BLC5 corresponding to the bit line may be disposed to extend in the first direction on the first front side wiring layer M1, and a pattern ABLC5 corresponding to the auxiliary bit line may be disposed to extend in the first direction on the backside wiring layer BM. A structure of the first region R1, the second region R2b, and the third region R_PERIb of the integrated circuit 60b of FIG. 7B may correspond to the structure of the integrated circuit 50b of FIG. 6B, and thus, redundant descriptions thereof are omitted for conciseness, and the second region R2a and the third region R_PERIa of the integrated circuit 60b are described.

The pattern BLC5 corresponding to the bit line and the pattern ABLC5 corresponding to the auxiliary bit line are not directly connected to each other, and the integrated circuit 60b has a structure for connecting one end of the second switch SW2b to the pattern ABLC5 corresponding to the auxiliary bit line, the integrated circuit 60b may include the two backside contact structures BCS extending in the Z-axis direction.

According to an embodiment of FIG. 7B, the two backside contact structures BCS extending in the Z-axis direction from both ends of the pattern ABLC5 corresponding to the auxiliary bit line and a transistor formed on a substrate may be connected to one ends of the second switches SW2a and SW2b, respectively. When the second switches SW2a and SW2b are turned on, the pattern ABLC5 corresponding to the auxiliary bit line and the pattern BLC5 corresponding to the bit line may be electrically connected to each other through the two backside contact structures BCS and the transistor formed on the substrate. According to an example of FIG. 7B, the backside contact structure BCS may be disposed in the third regions R_PERIa and R_PERIb, and to this end, the pattern BLC5 corresponding to the bit line and the pattern ABLC5 corresponding to the auxiliary bit line may be disposed to extend to the third regions R_PERIa and R_PERIb.

Referring to FIG. 7C, an integrated circuit 60c may include the first front side wiring layer M1 and the backside wiring layer BM. Referring to FIG. 7C, a pattern BLC6 corresponding to the bit line may be disposed to extend in the first direction on the first front side wiring layer M1, and a pattern ABLC6 corresponding to the auxiliary bit line may be disposed to extend in the first direction on the backside wiring layer BM. A structure of the first region R1, the second region R2b, and the third region R_PERIb of the integrated circuit 60c of FIG. 7C may correspond to the structure of the integrated circuit 50c shown in FIG. 6C, and thus, redundant descriptions thereof are omitted for conciseness, and the second region R2b and the third region R_PERIa of the integrated circuit 60c are described.

The integrated circuit 60c of FIG. 7C has a structure for connecting to the pattern ABLC6 corresponding to the auxiliary bit line, and may include the two backside contact structures BCS. The two backside contact structures BCS and the second switches SW2a and SW2b connected thereto may be disposed in the second regions R2a and R2b, respectively. Accordingly, the pattern ABLC6 corresponding to the auxiliary bit line may be disposed to extend only to the second regions R2a and R2b, and may not be formed in the third regions R_PERIa and R_PERIb.

Referring to FIG. 7D, an integrated circuit 60d may include the first front side wiring layer M1 and the backside wiring layer BM. Referring to FIG. 7D, a pattern BLC7 corresponding to the bit line may be disposed to extend in the first direction on the first front side wiring layer M1, and a pattern ABLC7 corresponding to the auxiliary bit line may be disposed to extend in the first direction on the backside wiring layer BM. Backside contact structures BCS1 and BCS2 for connecting the pattern ABLC7 corresponding to the auxiliary bit line to one ends of the second switches SW2a and SW2b may be connected to the pattern ABLC7 corresponding to the auxiliary bit line. According to the integrated circuit 60d of FIG. 7D, the backside contact structure BCS1 connected to one end of the second switch SW2a may be disposed in the second region R2b, and the backside contact structure BCS2 connected to one end of the second switch SW2b may be disposed in the third region R_PERIa. As described above, the backside contact structure for connecting the pattern ABLC7 corresponding to the auxiliary bit line to one end of the second switches SW2a and SW2b may be disposed in different regions at both ends of the pattern ABLC7 corresponding to the auxiliary bit line. According to another example, backside structures for respectively connecting to one ends of the second switches SW2a and SW2b may be of different types at both ends, and furthermore, backside structures for respectively connecting to one ends of the second switches SW2a and SW2b may be disposed in different regions. According to an embodiment, one end of the second switch SW2a may be connected to a backside via structure disposed in a second region, and one end of the second switch SW2b may be connected to a backside contact structure disposed in a second region. According to an example, one end of the second switch SW2a may be connected to the backside contact structure disposed in the second region, and one end of the second switch SW2b may be connected to the backside via structure disposed in the third region.

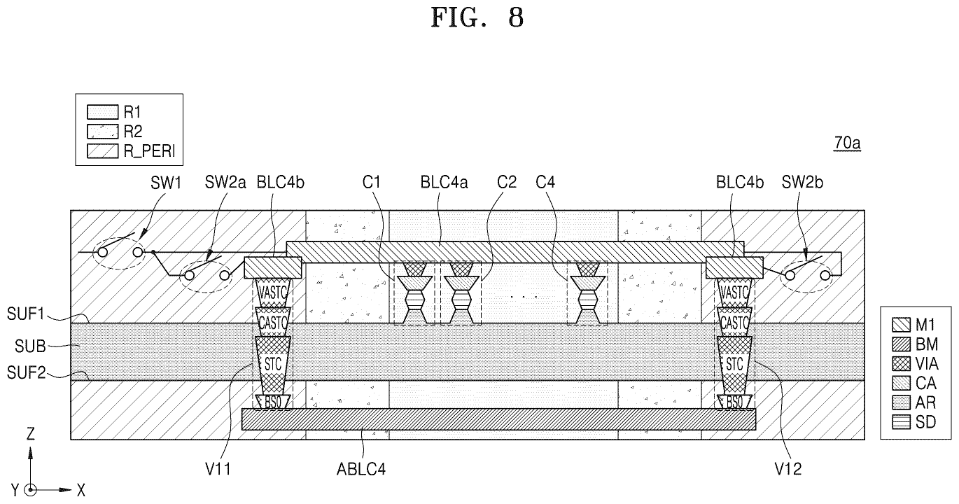

FIG. 8 is a cross-sectional view of an integrated circuit according to an embodiment.

In the cross-sectional view of an integrated circuit 70a of FIG. 8, patterns BLC4a and BLC4b corresponding to bit lines and a pattern ABLC4 corresponding to an auxiliary bit line are disposed in the first region R1, the second region R2, and the third region R_PERI. According to an example, the cross-sectional view of FIG. 8 may be a cross-sectional view corresponding to the embodiment of FIG. 7A. Accordingly, descriptions of configurations redundant with those described with reference to FIG. 7A will be omitted.

In FIG. 8, patterns BLC4a and BLC4b corresponding to bit lines are shown to have a step on a cross-sectional view, and it should be noted that this step is to indicate in the cross-sectional view that the patterns BLC4a and BLC4b corresponding to the bit lines are different and spaced apart from each other in the Y-axis direction. The patterns BLC4a and BLC4b corresponding to the bit lines may be disposed to be spaced apart from each other in the second direction on the first front side wiring layer M1. For convenience of explanation, the pattern BLC4b corresponding to the bit line is shown not to cross the first region R1 and the second region R2, but the pattern BLC4b corresponding to the bit line may be disposed to extend over the first region R1, the second region R2, and the third region R_PERI. In the cross-sectional view of the integrated circuit 70a of FIG. 8, the pattern BLC4a corresponding to the bit line and the pattern ABLC4 corresponding to the auxiliary bit line are shown on the same plane, but it should be noted that this depiction is drawn in one cross-sectional view as if the pattern ABLC4 corresponding to the auxiliary bit line is disposed below the pattern ABLC4a corresponding to the bit line to display the pattern BLC4a corresponding to the bit line and the pattern ABLC4 corresponding to the auxiliary bit line, it should be noted that there are some differences from reality for the sake of displaying a single cross-section.

Referring to the integrated circuit 70a of FIG. 8, the pattern BLC4a corresponding to a bit line may be disposed over the first region R1, the second region R2, and the third region R_PERI in a direction of a front side SUF1 of a substrate sub. The pattern ABLC4 corresponding to the auxiliary bit line may be disposed in a direction of a backside SUF2 of a substrate SUB over the first region R1, the second region R2, and the third region R_PERI. The pattern BLC4a corresponding to the bit line and the pattern ABLC4 corresponding to the auxiliary bit line may extend in the first direction.

In the first region R1, structures corresponding to the plurality of memory cells C1, C2, . . . , C4 may be disposed on the substrate SUB. Each of the structures may be configured by vertically stacking an active region AR, a source/drain region S/D, a contact CA, and a via VA. Each of the structures disposed on the substrate SUB may be physically connected to the pattern BLC4a corresponding to the bit line.

According to an example, the pattern ABLC4 corresponding to the auxiliary bit line may be physically connected to the pattern BLC4b corresponding to the bit line through the backside via structures V11 and V12 vertically penetrating the substrate SUB. According to an example, the backside via structures V11 and V12 vertically penetrating the substrate SUB may be formed by sequentially stacking a plurality of vias BS0, STC, CASTC, and VASTC. According to another example, the backside via structures V11 and V12 may be provided as one through silicon via structure. A structure of the backside via structures V11 and V12 may not be limited to that shown in FIG. 8, and may be changed in various ways and provided in a structure capable of physically connecting the pattern ABLC4 corresponding to the auxiliary bit line disposed on the backside of the substrate SUB to the pattern BLC4b corresponding to the bit line disposed on the front side of the substrate SUB. In the disclosure, a backside via structure may mean a structure including at least one via formed by penetrating a substrate to connect a wiring disposed on the backside of the substrate to other components disposed on the front side of the substrate.

Referring back to FIG. 8, the first switch SW1 and the second switches SW2a and SW2b may be disposed in the peripheral region R_PERI of the integrated circuit 70a, one end of the first switch SW1 may be connected to the pattern BLC4a corresponding to the bit line, and the second switches SW2a and SW2b may be connected to one end of the pattern BLC4b corresponding to the bit line physically connected to the backside via structures V11 and V12.

According to an example, the backside via structures V11 and V12 and the second switches SW2a and SW2b may be formed in the peripheral region R_PERI, the pattern BLC4b corresponding to the bit line disposed on the front side of the substrate SUB and the pattern ABLC4 corresponding to the auxiliary bit line disposed in the backside of the substrate SUB may be connected to each other through the backside via structures V11 and V12, and the pattern BLC4a corresponding to the bit line and the pattern ABLC4 corresponding to the auxiliary bit line may be electrically connected to each other by connection between the second switches SW2a and SW2b.

FIG. 8 shows only a configuration in which the backside via structures V11 and V12 are disposed in the peripheral region R_PERI, but the backside via structures V11 and V12 may be disposed in the second region R2.

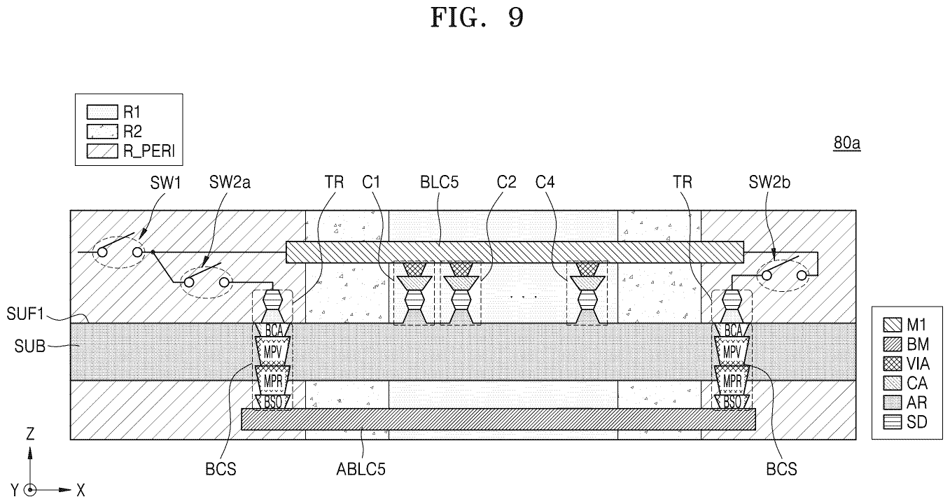

FIG. 9 is a cross-sectional view of an integrated circuit according to an embodiment.

In the cross-sectional view of an integrated circuit 80a of FIG. 9, a pattern BLC5 corresponding to a bit line and a pattern ABLC5 corresponding to an auxiliary bit line are disposed in the first region R1, the second region R2, and the third region R_PERI. According to an example, the cross-sectional view of FIG. 9 may be a cross-sectional view corresponding to the embodiment of FIG. 7B. Accordingly, descriptions of configurations redundant with those described with reference to FIG. 7B will be omitted for conciseness.

In the cross-sectional view of the integrated circuit 80a of FIG. 9, the pattern BLC5 corresponding to the bit line and the pattern ABLC5 corresponding to the auxiliary bit line are shown on the same plane, but it should be noted that this depiction is drawn in one cross-sectional view as if the pattern ABLC5 corresponding to the auxiliary bit line is disposed below the pattern BLC5 corresponding to the bit line to display the pattern BLC5 corresponding to the bit line and the pattern ABLC5 corresponding to the auxiliary bit line, it should be noted that there are some differences from reality for the sake of displaying a single cross-section.

In the first region R1, the pattern BLC5 corresponding to the bit line may be connected to a structure corresponding to the plurality of memory cells C1, C2, and C4.

In the third region R_PERI, the backside contact structure BCS for connecting the pattern ABLC5 corresponding to the auxiliary bit line to the second switches SW2a and SW2b may be disposed. The backside contact structure BCS may be in contact with the pattern ABLC5 corresponding to the auxiliary bit line, and may be formed to penetrate the substrate SUB. In the disclosure, a backside contact structure may refer to a structure including at least one via formed by penetrating a substrate to connect a wiring disposed on the backside of the substrate to other components disposed on the front side of the substrate and at least one contact.

The backside contact structure BCS may include a plurality of stacked vias BS0, MPR, and MPV and a backside contact BCA stacked on the plurality of stacked vias BS0, MPR, and MPV. According to an example, the backside contact BCA may be a component corresponding to the backside contact CT described with reference to FIGS. 6A to 7D. According to an example, configurations of the plurality of stacked vias BS0, MPR, and MPV included in the backside contact structure BCS may not be limited to those shown in FIG. 9. The backside contact BCA of the backside contact structure BCS may be in contact with the front side SUF1 of the substrate SUB. The backside contact BCA may be in contact with a transistor TR formed on the front side SUF1 of the substrate SUB, and accordingly, may be connected to one ends of the second switches SW2a and SW2b. According to an example, the backside contact structure BCS and the transistor TR connected thereto may be disposed in the third region R_PERI.

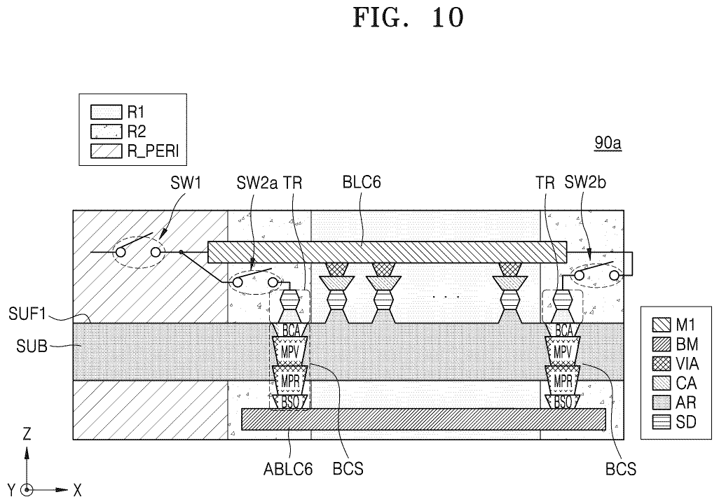

FIG. 10 is a cross-sectional view of an integrated circuit according to an embodiment.

In the cross-sectional view of an integrated circuit 90a of FIG. 10, a pattern BLC6 corresponding to a bit line and a pattern ABLC6 corresponding to an auxiliary bit line are formed in the first region R1, the second region R2, and the third region R_PERI. According to an example, the cross-sectional view of FIG. 10 may be a cross-sectional view corresponding to the embodiment of FIG. 7C. Accordingly, descriptions of configurations redundant with those described with reference to FIG. 7C will be omitted for conciseness.

In the cross-sectional view of the integrated circuit 90a of FIG. 10, the pattern BLC6 corresponding to the bit line and the pattern ABLC6 corresponding to the auxiliary bit line are shown on the same plane, but it should be noted that this depiction is drawn in one cross-sectional view as if the pattern ABLC6 corresponding to the auxiliary bit line is disposed below the pattern BLC6 corresponding to the bit line to display the pattern BLC6 corresponding to the bit line and the pattern ABLC6 corresponding to the auxiliary bit line, it should be noted that there are some differences from reality for the sake of displaying a single cross-section.

In the integrated circuit 90a of FIG. 10, the backside contact structure BCS for connecting the pattern ABLC6 corresponding to the auxiliary bit line to the second switches SW2a and SW2b may be disposed in the second region R2. The backside contact structure BCS may be in contact with the pattern ABLC6 corresponding to the auxiliary bit line, and may be formed to penetrate the substrate SUB.

The backside contact structure BCS may include the plurality of stacked vias BS0, MPR, and MPV and the backside contact BCA stacked on the plurality of stacked vias BS0, MPR, and MPV. According to an example, configurations of the plurality of stacked vias BS0, MPR, and MPV included in the backside contact structure BCS may not be limited to those shown in FIG. 10. The backside contact BCA of the backside contact structure BCS may be in contact with the front side SUF1 of the substrate SUB. The backside contact BCA may be in contact with the transistor TR formed on the front side SUF1 of the substrate SUB, and accordingly, may be connected to one ends of the second switches SW2a and SW2b. According to an example, the backside contact structure BCS, the transistor TR connected thereto, and the second switches SW2a and SW2b are disposed in the second region R2 to utilize a dummy cell region, and thus the performance of a memory cell may be improved without the overhead of an area.

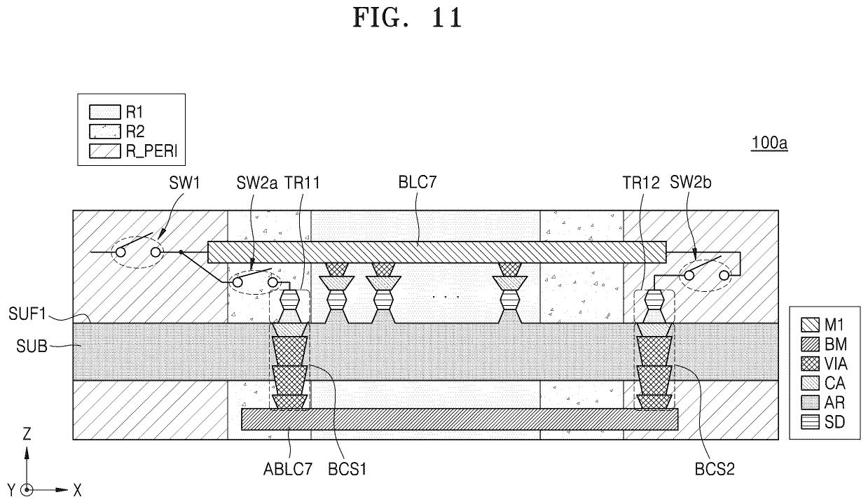

FIG. 11 is a cross-sectional view of an integrated circuit according to an embodiment.

In the cross-sectional view of an integrated circuit 100a of FIG. 11, a pattern BLC7 corresponding to a bit line and a pattern ABLC7 corresponding to an auxiliary bit line are formed in the first region R1, the second region R2, and the third region R_PERI. According to an example, the cross-sectional view of FIG. 11 may be a cross-sectional view corresponding to the embodiment of FIG. 7D. Accordingly, descriptions of configurations redundant with those described with reference to FIG. 7D will be omitted for conciseness.

In the cross-sectional view of the integrated circuit 100a of FIG. 11, the pattern BLC7 corresponding to the bit line and the pattern ABLC7 corresponding to the auxiliary bit line are shown on the same plane, but it should be noted that this is drawn in one cross-sectional view as if the pattern ABLC7 corresponding to the auxiliary bit line is disposed below the pattern BLC7 corresponding to the bit line to display the pattern BLC7 corresponding to the bit line and the pattern ABLC7 corresponding to the auxiliary bit line, it should be noted that there are some differences from reality for the sake of displaying a single cross-section.

Referring to FIG. 11, the backside contact structures BCS1 and BCS2 may be in contact with and connected to the pattern ABLC7 corresponding to the auxiliary bit line. According to an example, the backside contact structure BCS1 may be connected to one end of the second switch SW2a through a first transistor TR11, and the backside contact structure BCS2 may be connected to one end of the second switch SW2b through a second transistor TR12.

In the integrated circuit 100a according to an embodiment, the backside contact structure BCS1 and the second switch SW2a may be disposed in the second region R2, and the backside contact structure BCS2 and the second switch SW2b may be disposed in the third region R_PERI. As described above, backside connection structures may be disposed using regions of various combinations.

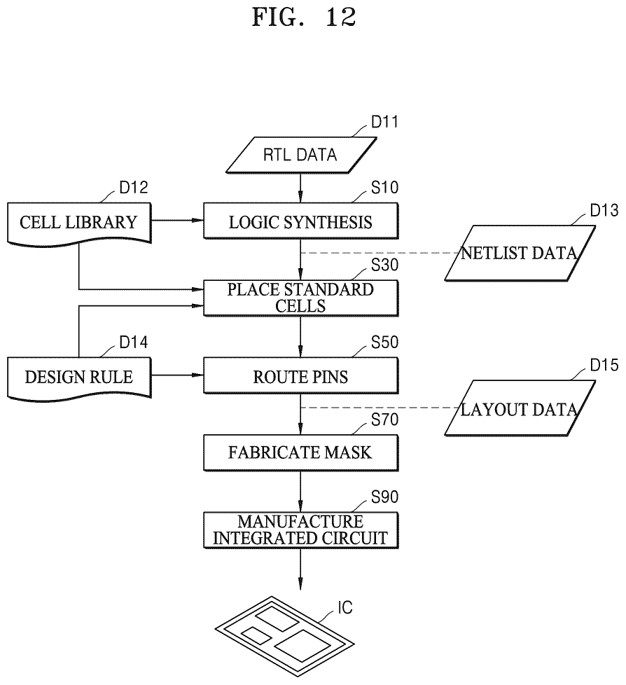

FIG. 12 is a flowchart illustrating a method of manufacturing an integrated circuit IC according to an embodiment.

Referring to FIG. 12, the method according to the embodiment, as the method of manufacturing the integrated circuit IC including bit cells and standard cells, may include a plurality of operations S10, S30, S50, S70, and S90. A cell library (or a standard cell library) D12 may include information about standard cells, such as information about function, characteristics, layout, etc. In an embodiment, the cell library D12 may define tap cells, filler cells, and dummy cells, as well as functional cells that generate output signals from input signals. In an embodiment, the cell library D12 may define a plurality of bit cells. The design rule D14 may include requirements that the layout of the integrated circuit IC needs to comply with. For example, the design rule D14 may include requirements with respect to spaces between patterns on the same layer, a minimum width of a pattern, a routing direction of a wiring layer, etc.

In operation S10, a logic synthesis operation of generating netlist data D13 from RTL data D11 may be performed. For example, a semiconductor design tool (e.g., a logic synthesis tool) may perform logic synthesis by referencing the cell library D12 from the RTL data D11 written in a VHSIC hardware description language (VHDL) and hardware description language (HDL), such as Verilog, and may generate the netlist data D13 including a bitstream or netlist. The netlist data D13 may correspond to input of place and routing described below.

In operation S30, standard cells may be disposed. For example, a semiconductor design tool (e.g., a P&R tool) may place the standard cells used in the netlist data D13 by referencing the cell library D12. A plurality of bit cells may be disposed. For example, the semiconductor design tool may place the bit cells together with the standard cells.

In operation S50, pins of the standard cells may be routed. For example, the semiconductor design tool may generate interconnections that electrically connect output pins to input pins of the placed standard cells and generate layout data D15 defining the placed standard cells and the generated interconnections. The interconnections may include via of a via layer and/or patterns of wiring layers. The wiring layers may include a front side wiring layer disposed on top of the front side of a substrate and a backside wiring layer disposed on the backside of the substrate. The layout data D15 may have a format, such as GDSII, and may include geometric information of cells and interconnections. The semiconductor design tool may refer to the design rule D14 while routing the pins of cells. The layout data D15 may correspond to output of place and routing. Operation S50 alone or operations S30 and S50 collectively may be referred to as the method of designing the integrated circuit IC.

In an embodiment, as shown in FIGS. 1 to 11, the integrated circuit IC may include patterns extending from the backside wiring layer below the substrate and a backside contact structure or a backside via structure penetrating the substrate in a vertical direction. The patterns extending from the backside wiring layer may be used for auxiliary routing of signals (e.g., BLC and BLT). Accordingly, routing resources in the bit cell array 11 may increase, parasitic components of a pattern may decrease, and thus, the performance and reliability of the memory device 10 may increase. In addition, the backside contact structure or the backside via structure may be disposed in the second region R2 or the third region R_PERI, so that the layout may be disposed to reduce the overhead of the area.

In operation S70, an operation of fabricating a mask may be performed. For example, optical proximity correction (OPC) to correct distortion phenomena, such as refraction caused by the characteristics of light in photolithography may be applied to the layout data D15. Patterns on the mask may be defined to form patterns disposed on a plurality of layers based on data to which OPC is applied, and at least one mask (or photomask) may be fabricated to form the respective patterns of a plurality of layers. In some embodiments, the layout of the integrated circuit IC may be limitedly modified in operation S70, and the limited modification of the integrated circuit IC in operation S70 may be referred to as design polishing as post-processing to optimize the structure of the integrated circuit IC.

In operation S90, an operation of manufacturing the integrated circuit IC may be performed. For example, the integrated circuit IC may be manufactured by patterning a plurality of layers using the at least one mask fabricated in operation S70. Front-end-of-line (FEOL) may include, for example, operations of planarizing a wafer, cleaning the wafer, forming a trench, forming a well, forming a gate line, and forming a source and a drain. By means of FEOL, individual components, such as transistors, capacitors, resistors, etc., may be formed on the substrate. Back-end-of-line (BEOL) may include, for example, operations of silicidating gate, source, and drain regions, adding a dielectric, planarizing, forming holes, adding a metal layer, forming a via, forming a passivation layer, etc. By means of BEOL, individual components, such as transistors, capacitors, resistors, etc. may be interconnected. In some embodiments, a middle-of-line (MOL) may be performed between the FEOL and the BEOL, and contacts may be formed on individual elements. Next, the integrated circuit IC may be packaged into a semiconductor package and used as a component in various applications.

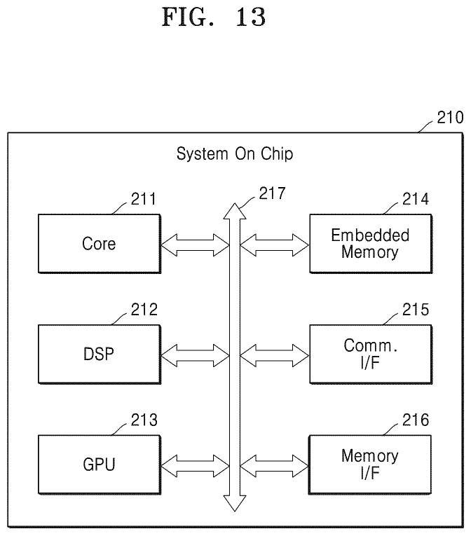

FIG. 13 is a block diagram illustrating a system-on-chip (SoC) 210 according to an embodiment.

Referring to FIG. 13, the SoC 210 may refer to an integrated circuit that integrates components of a computing system or another electronic system. For example, as an example of the SoC 210, an application processor (AP) may include a processor and components for other functions. The SoC 210 may include a core 211, a digital signal processor (DSP) 212, a graphics processing unit (GPU) 213, an embedded memory 214, a communication interface (I/F) 215, and a memory interface (I/F) 216. Components of the SoC 210 may communicate with each other through a bus 217.

The core 211 may process instructions and control the operation of components included in the SoC 210. For example, the core 211 may drive an operating system and execute applications on the operating system by processing a series of instructions. The DSP 212 may generate useful data by processing a digital signal, for example, a digital signal provided from the communication interface 215. The GPU 213 may generate data for an image output through a display device from image data provided from the embedded memory 214 or the memory interface (I/F) 216 or may encode the image data. In some embodiments, the integrated circuit described above with reference to the drawings may be included in the core 211, the DSP 212, the GPU 213 and/or the embedded memory 214.

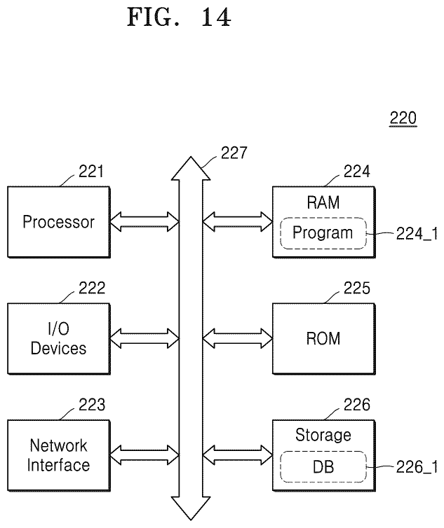

FIG. 14 is a block diagram illustrating a computing system 220 including a memory storing a program according to an embodiment.

Referring to FIG. 14, a method of designing an integrated circuit according to some embodiments, for example, at least some of the operations of the flowchart described above with respect to FIG. 12, may be performed in the computing system 220 (or a computer). The computing system 220 may include a processor 221, I/O devices 222, a network interface 223, a random access memory (RAM) 224, a read only memory (ROM) 225, and a storage 226. The processor 221, the I/O devices 222, the network interface 223, the RAM 224, the ROM 225, and the storage 226 may be connected to a bus 227 and communicate with each other via a bus 227.

The processor 221 may access memory, i.e., the RAM 224 or the ROM 225, through the bus 227 and execute instructions stored in the RAM 224 or the ROM 225. The RAM 224 may store a program 224_1 or at least a part thereof for the method of designing the integrated circuit according to an embodiment, and the program 224_1 may cause the processor 221 to perform the method of designing the integrated circuit, for example, at least some of the operations included in the methods of FIG. 12. That is, the program 224_1 may include a plurality of instructions executable by the processor 221, and the plurality of instructions included in the program 224_1 may cause the processor 221 to perform, for example, at least some of the operations included in the flowcharts described above.

The storage 226 may store the program 224_1 according to an embodiment. In addition, the storage 226 may store a database (DB) 226_1, and the database 226_1 may include information for designing the integrated circuit, such as information about designed blocks, the cell library D12 and/or design rule D14 of FIG. 12. The storage 226 may store data to be processed by the processor 221 or data processed by the processor 221. For example, the storage 226 may store the RTL data D11, the netlist data D13 and/or the layout data D15 of FIG. 12.

While various embodiments have been particularly shown and described with reference to the drawings, it will be understood that various changes in form and details may be made therein without departing from the spirit and scope of the following claims.

What is claimed is:

1. An integrated circuit comprising:
a cell region in which a plurality of cells are disposed; and
a peripheral region in which a circuit controlling the plurality of cells is disposed,
wherein the cell region comprises:
a bit cell region in which bit cells among the plurality of cells are disposed; and
a dummy region in which dummy cells among the plurality of cells are disposed,
wherein in the cell region, a bit line pattern and an auxiliary bit line pattern are disposed, the bit line pattern extending in a first direction from a front side of a substrate on which the plurality of cells are disposed, and the auxiliary bit line pattern extending in the first direction from a backside of the substrate, and
wherein the bit line pattern and the auxiliary bit line pattern are configured to be electrically connected to each other in a write mode of the plurality of cells.

2. The integrated circuit of claim 1, wherein each of the plurality of cells is a static random-access memory cell.

3. The integrated circuit of claim 1, further comprising:
a backside via structure that vertically penetrates the substrate and that is in contact with the auxiliary bit line pattern.

4. The integrated circuit of claim 3, wherein the backside via structure is disposed in the peripheral region.

5. The integrated circuit of claim 3, wherein the backside via structure is disposed in the dummy region.

6. The integrated circuit of claim 1, further comprising:
a backside contact structure that vertically penetrates the substrate and that is in contact with the auxiliary bit line pattern.

7. The integrated circuit of claim 6, wherein the backside contact structure is disposed in the peripheral region.

8. The integrated circuit of claim 6, wherein the backside contact structure is disposed in the dummy region.

9. The integrated circuit of claim 1, further comprising:
a switch configured to be turned on in the write mode of the plurality of cells to connect one end of the bit line pattern to one end of the auxiliary bit line pattern.

10. An integrated circuit comprising:
a first region in which a plurality of bit cells are disposed;
a second region provided to surround the first region; and
a third region in which a circuit controlling the plurality of bit cells is disposed,
wherein, in the integrated circuit, a bit line pattern and an auxiliary bit line pattern are disposed, the bit line pattern extending in a first direction from a front side of a substrate on which the plurality of bit cells are disposed, and the auxiliary bit line pattern extending in the first direction from a backside of the substrate, and
wherein the integrated circuit further comprises a backside connection structure that is connected to the auxiliary bit line pattern and that vertically penetrates the substrate.

11. The integrated circuit of claim 10, wherein the backside connection structure is disposed in the second region.

12. The integrated circuit of claim 10, wherein the backside connection structure is disposed in the third region.

13. The integrated circuit of claim 10, wherein the backside connection structure is a backside via structure.

14. The integrated circuit of claim 10, wherein the backside connection structure is a backside contact structure.

15. The integrated circuit of claim 10, further comprising:
a switch connected between the bit line pattern and the auxiliary bit line pattern to electrically connect the bit line pattern to the auxiliary bit line pattern in a write mode of the plurality of bit cells.

16. The integrated circuit of claim 15, wherein the switch is disposed in a same region as the backside connection structure.

17. An integrated circuit comprising:
a cell region in which a plurality of cells are arranged; and
a peripheral region in which a circuit controlling the plurality of cells is disposed,
wherein:
in the cell region, a bit line, a complementary bit line, an auxiliary bit line and an auxiliary complementary bit line are disposed,
the bit line and the complementary bit line are commonly connected to cells arranged in a same column among the plurality of cells,
the auxiliary bit line is connected in parallel to the bit line through a switch, and the auxiliary complementary bit line is connected in parallel to the complementary bit line through the switch,
the bit line and the complementary bit line are disposed on a front side wiring layer with respect to a substrate on which the plurality of cells are disposed,
the auxiliary bit line and the auxiliary complementary bit line are disposed on a backside wiring layer with respect to the substrate, and
the switch is configured to be turned on in a write mode of the plurality of cells.

18. The integrated circuit of claim 17, further comprising:
a backside connection structure that penetrates the substrate and that is in contact with a pattern corresponding to the auxiliary bit line.

19. The integrated circuit of claim 18, wherein the backside connection structure is disposed in the peripheral region.

20. The integrated circuit of claim 18, wherein the backside connection structure is disposed in a region of the cell region in which dummy cells are disposed.
